(19) United States
(12) Patent Application Publication
(10) Pub. No.: US 2011/0133225 A1
(43) Pub. Date: Jun. 9, 2011

(54) LIGHT COLLECTION SYSTEM FOR AN LED LUMINAIRE

(75) Inventor: Pavel Jurik, Postredni Becva (CZ)

(73) Assignee: ROBE LIGHTING S.R.O

(21) Appl. No.: 12/729,079

(22) Filed: Mar. 22, 2010

Related U.S. Application Data
(63) Continuation of application No. 12/581,788, filed on Oct. 19, 2009.
(60) Provisional application No. 61/106,969, filed on Oct. 20, 2008.

(51) Int. Cl. H01L 33/00

(52) U.S. Cl. 257/89; 257/E33.06

(57) ABSTRACT

A light beam collection engine 320 for LED array or other multi-source light luminaries 360. The light beam collection system incorporates a light integrator 306 which collects and integrates/homogenizes the light from a plurality of light sources 140 in configured in an array 130. The engine 320 is particularly useful in luminaries 360 that are used in light systems that employ beam modulation elements 362, 364, 366 where it is desirable to have a tight or narrow light beam.

### RELATED APPLICATION(S)

This application is a utility continuation application of utility application Ser. No. 12581788 filed 19 Oct. 2009 claiming priority of provisional application 61/106,969 filed on 20 Oct. 2008.

### TECHNICAL FIELD OF THE INVENTION

The present invention generally relates to a method for controlling the light output from an array of LEDs when used in a light beam producing luminaire, specifically to a method relating to improving light collection efficiency and beam homogenization.

### BACKGROUND OF THE INVENTION

High power LEDs are commonly used in luminaires for example in the architectural lighting industry in stores, offices and businesses; and/or in the entertainment industry in theatres, television studios, concerts, theme parks, night clubs and other venues. These LEDs are also being utilized in automated lighting luminaires with automated and remotely controllable functionality. For color control it is common to use an array of LEDs of different colors. For example a common configuration is to use a mix of Red, Green and Blue LEDs. This configuration allows the user to create the color they desire by mixing appropriate levels of the three colors. For example illuminating the Red and Green LEDs while leaving the Blue extinguished will result in an output that appears Yellow. Similarly Red and Blue will result in Magenta and Blue and Green will result in Cyan. By judicious control of the LED controls the user may achieve any color they desire within the color gamut set by the LED colors in the array. More than three colors may also be used and it is well known to add an Amber or White LED to the Red, Green and Blue to enhance the color mixing and improve the gamut of colors available.

The optical systems of such luminaires may include a gate or aperture through which the light is constrained to pass. Mounted in or near this gate may be devices such as gobos, patterns, irises, color filters or other beam modifying devices as known in the art.

A typical product will often provide control over the pan and tilt functions of the luminaire allowing the operator to control the direction the luminaire is pointing and thus the position of the light beam on the stage or in the studio. Additionally the light may offer multiple remotely selectable patterns or gobos containing images that the operator can select and project. Such gobos may be rotatable, also under remote control, or static. The light may further offer color control systems that provide either or both fixed color filters or color mixing systems based on subtractive colors.

FIG. 1 illustrates a prior art system 100 where a light source 102 is positioned at or close to one of the focal points 104 of an elliptical reflector 106 such that the light 108 from light source 102 is reflected by the reflector 106 towards the second focal point 110 of the reflector 106. Aperture 112 is positioned close to the second focal point 110 of reflector 106 and a substantial proportion of the light 108 from light source 102 will pass through this aperture 112 and into downstream optics (not shown).

FIG. 2 illustrates a system 120 resulting from attempts to mimic a beam generation systems like the ones illustrated in FIG. 1 with an array 130 of LEDs 140. Each LED 140 has an associated optical system which may include reflectors, TIR devices, diffusers, gratings or other well known optical devices so as to direct the light from the LED 140 in a narrow beam towards aperture 112. However, the array of LEDs 140 may be large compared to the aperture 112 and each LED 140 may be of differing colors. This causes the light beam when it passes through the aperture 112 to be non-homogeneous with respect to color and distribution resulting in an unsatisfactory output from the luminaire where different areas are different in color and output. An example of such a system 120 is disclosed in U.S. Pat. No. 7,152,996 by Luk. These attempts have also been made where the LEDs 140 are configured to mimic the shape of the elliptical reflector 106 like that in FIG. 1.

Additionally the large size of the LED array 130 and the necessary spacing between the LED array 130 and the aperture 112 compared to the aperture 112 may result in very inefficient coupling of light from the array 130 through the aperture 112 with much of the light 108 from LEDs 140 missing aperture 112 or spreading outside of its periphery.

There is a need for a light collection system for an LED array based luminaire which can efficiently gather the light emitted from the LED array, homogenize the beam and deliver it to an aperture and downstream optical systems.

### BRIEF DESCRIPTION OF THE DRAWINGS

For a more complete understanding of the present invention and the advantages thereof, reference is now made to the following description taken in conjunction with the accompanying drawings in which like reference numerals indicate like features and wherein:

FIG. 1 illustrates a prior art light collection beam generation system;

FIG. 2 illustrates another prior art light collection beam generation system;

FIG. 3 illustrates perspective view of an embodiment of the invention;

FIG. 4 illustrates a cross-sectional layout diagram of an embodiment of the invention;

FIG. 5 illustrates a cross-sectional layout diagram of an embodiment of the invention;

FIG. 6 illustrates a cross-sectional layout diagram of an exemplary embodiment of the invention;

FIG. 7 illustrates a perspective view of an exemplary embodiment of the invention;

FIG. 8 illustrates a cross-sectional layout diagram of an embodiment of the invention;

FIG. 9 illustrates a cross-sectional layout diagram of an embodiment of the invention;

FIG. 10 illustrates a cross-sectional layout diagram of an embodiment of the invention;

FIG. 11 illustrates a cross-sectional layout diagram of an embodiment of the invention;

FIG. 12 illustrates a cross-sectional layout diagram of an embodiment of the invention;

FIG. 13 illustrates a cross-sectional layout diagram of an embodiment of the invention;

FIG. 14 illustrates a cross-sectional layout diagram of an embodiment of the invention; and

FIG. 15 illustrates a cross-sectional layout diagram of an embodiment of the invention.

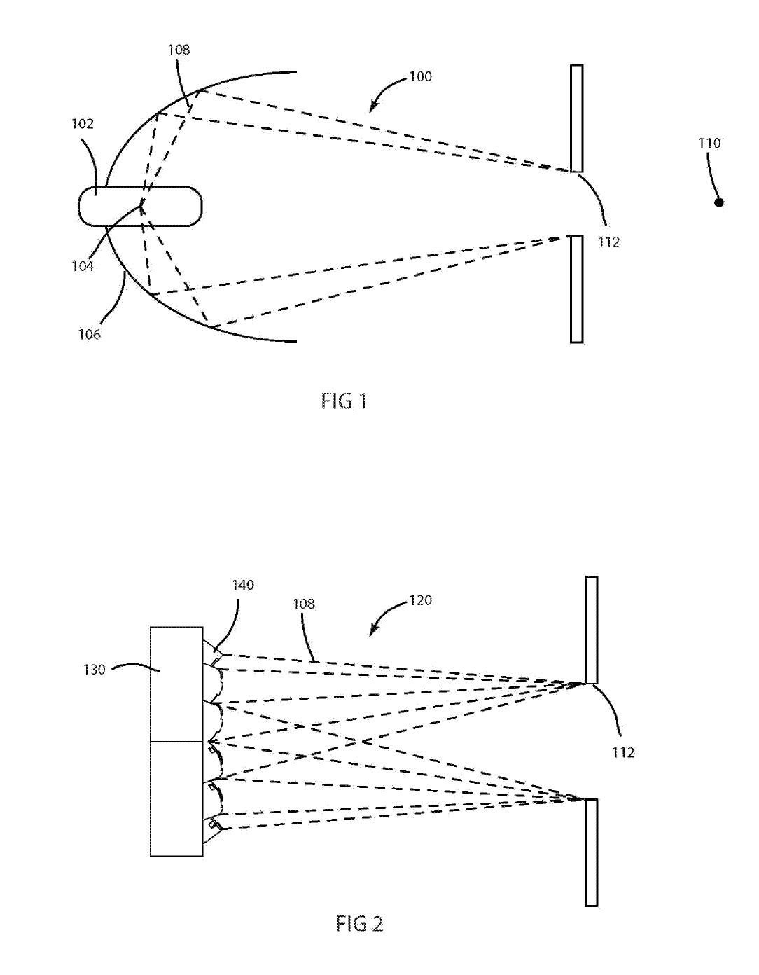

### DETAILED DESCRIPTION OF THE INVENTION

Preferred embodiments of the present invention are illustrated in the FIGUREs, like numerals being used to refer to like and corresponding parts of the various drawings.

The present invention generally relates to a method for controlling the light output from an array of LEDs when used in a light beam producing luminaire, specifically to a method relating to improving light collection efficiency and beam homogenization of the array.

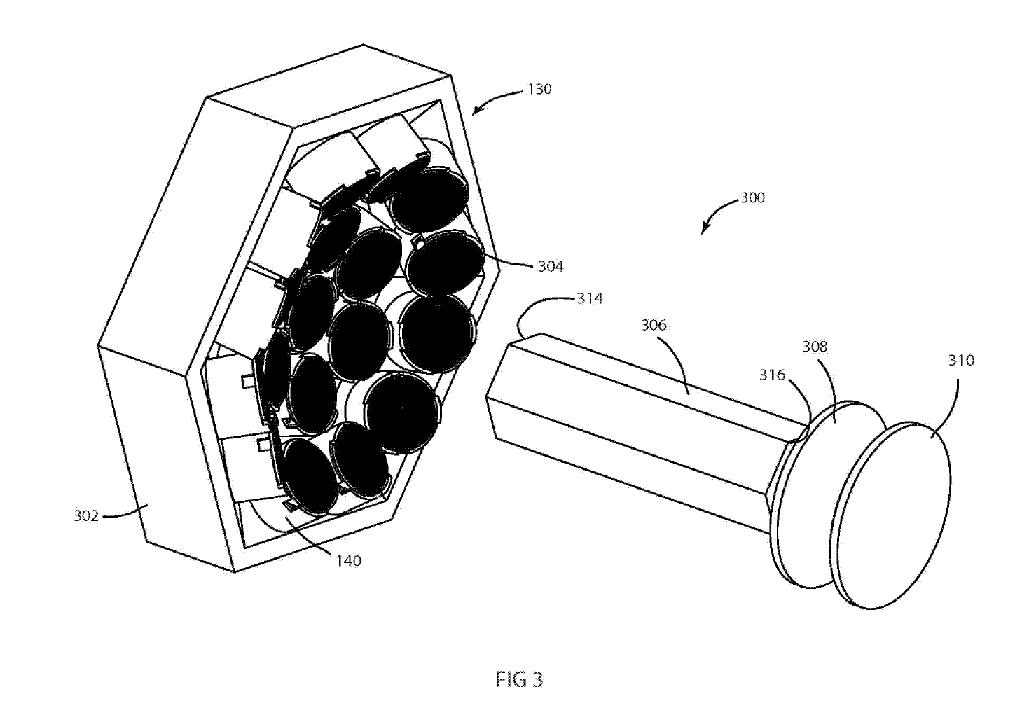

FIG. 3 illustrates an embodiment of an LED collection system 300 the invention where an array of LED light sources 140 are mounted to a carrier 302 such that each LED light source in the array is generally aimed towards light integrator 306. Each LED light source 140 may be fitted with its own optical element 304. Optical element 304 is an optional component in the system and may be a lens, lens array, micro-lens array, holographic grating, diffractive grating, diffuser, or other optical device known in the art the purpose of which is to control and direct the light from LED light source 140 towards the entry port 314 of the light integrator 306. Each LED light source element 140 may contain a single LED die or an array of LED dies utilizing the same optical element 304. Such arrays of LED dies within LED light source 140 may be of a single color and type or may be of multiple colors such as a mix of Red, Green and Blue LEDs. Any number and mix of colors of LED dies may be used within each LED light source 140 without departing from the spirit of the invention.

Light integrator 306 is a device utilizing internal reflection so as to homogenize and constrain the light from LED light sources 140. Light integrator 306 may be a hollow tube with a reflective inner surface such that light impinging into the entry port 314 may be reflected multiple times along the tube before leaving at the exit port 316. As the light is reflected down the tube in different directions from each LED light source 140 the light beams will mix forming a composite beam where different colors of light are homogenized and an evenly colored beam is emitted. Light integrator 306 may be a square tube, a hexagonal tube, a circular tube, an octagonal tube or a tube of any other cross section. In a further embodiment light integrator 306 may be a solid rod constructed of glass, transparent plastic or other optically transparent material where the reflection of the incident light beam within the rod is due to total internal reflection (TIR) from the interface between the material of the rod and the surrounding air. The integrating rods may be circular, other polygonal or irregular cross-sectional shape.

The homogenized light exits from the light integrator 306 and may then be further controlled and directed by other optical elements 308 and 310. Optical system 308 and 310 may be condensing lenses designed to produce an even illumination for additional downstream optics (described below).

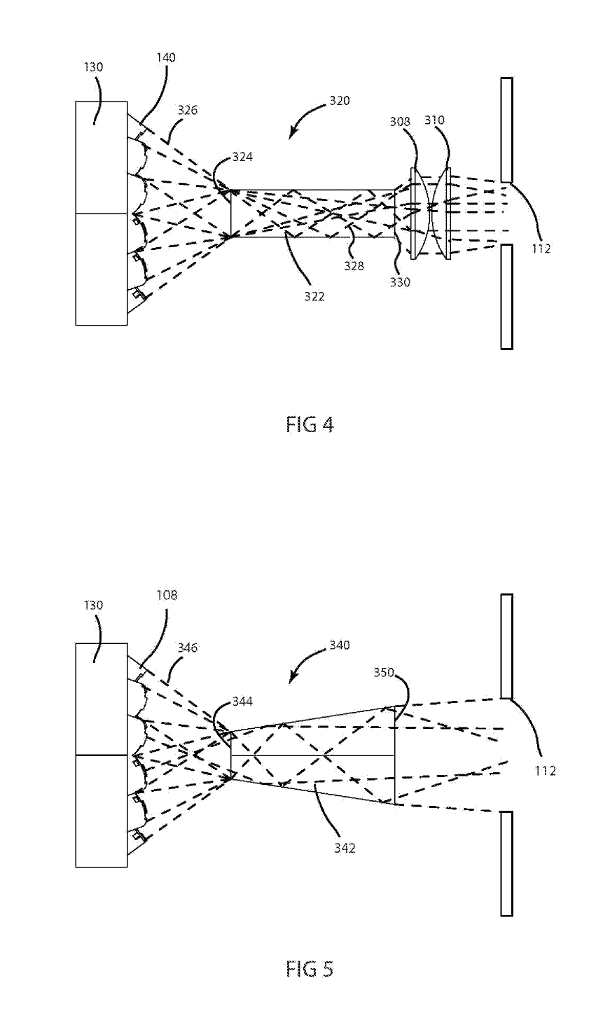

FIG. 4 illustrates a layout diagram of an embodiment of the invention showing the approximate path of light as it passes through the system 320. An array of LED light sources 140 each direct light 326 into the entrance aperture 324 of light integrator 322. Within light integrator 322 the light beams 328 may reflect from the walls any number of times from zero to a number defined by the geometry of the tube 322 and the entrance angle and position of the incident light. This variation in path length and the different numbers of reflections causes homogenization of the light beams within light integrator 322. A feature of a light integrator 322 which comprises a hollow or tube or solid rod where the sides of the rod or tube are essentially parallel and the entrance aperture 324 and exit aperture 330 are of the same size is that the divergence angle of light exiting the integrator 322 will be the same as the divergence angle for light 326 entering the integrator 322. Thus a parallel-sided integrator 322 has no effect on the beam divergence. Light exiting the light integrator 322 is further controlled and directed by optical elements 308 and 310 which may form a conventional condensing lens system, to direct light towards aperture 112. Condensor lens systems tend to collimate the light and produce a more parallel beam. Although two optical elements 308 and 310 are herein illustrated the invention is not so limited and any optical system as known in the art may be utilized to direct the exit beam towards aperture 112.

FIG. 5 illustrates a layout diagram of a further embodiment 340 of the invention showing the approximate path of light as it passes through the system 340. An array of LED light sources 140 directs light into the entrance aperture 344 of tapered light integrator 342. Within tapered light integrator 342 the light beams 346 may reflect from the walls any number of times from zero to a number defined by the geometry of the tube and the entrance angle and position of the incident light. This variation in path length and the different numbers of reflections causes homogenization of the light beams within light integrator 342. A feature of a tapered light integrator 342 which comprises a hollow or tube or solid rod where the sides of the rod or tube are tapered and the entrance aperture 344 is smaller than the exit aperture 350 is that the divergence angle of light exiting the integrator 342 will be smaller than the divergence angle for light entering the integrator 342. The combination of a smaller divergence angle from a larger aperture 350 serves to conserve the etendue of the system 340. Etendue is a measure of the light spread in an optical system and remains constant throughout the system. In this case the etendue relates to the product of the aperture size and the divergence angle into or out of that aperture. Increasing the size of the aperture causes a corresponding decrease in divergence angle and vice-versa. Thus a tapered integrator 342 may provide similar functionality to the condensing optical system 308 and 310 illustrated in FIG. 4 and light may be delivered directly to aperture 112 without any need for further optical components to control and shape the beam.

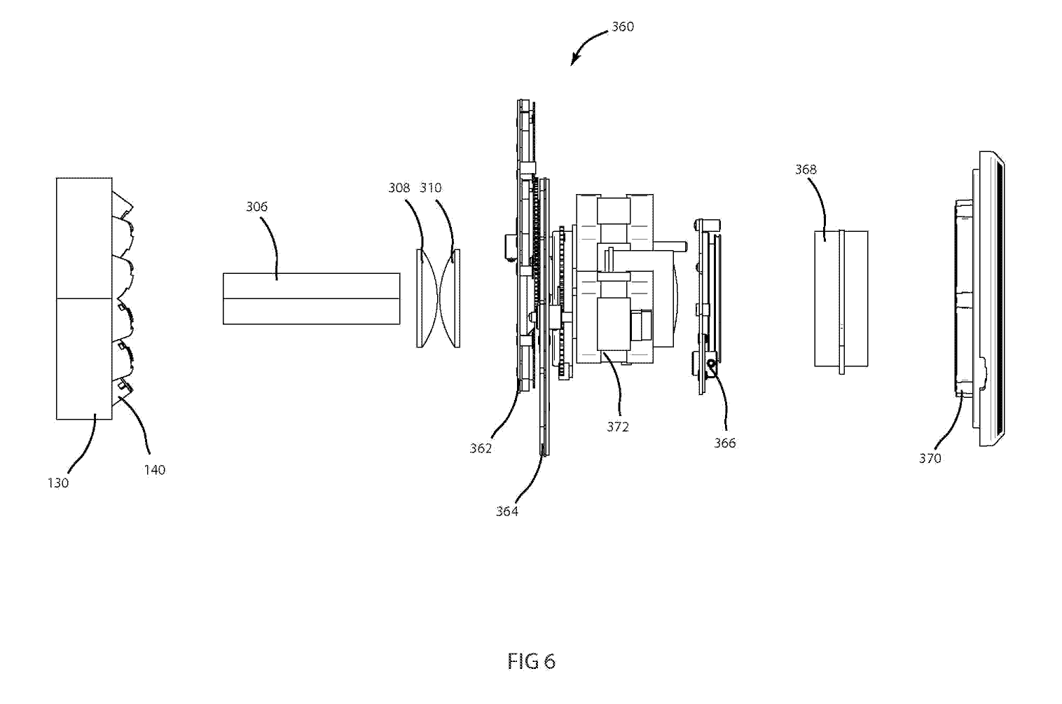

FIG. 6 illustrates an exemplary embodiment 360 of the invention as it may be used in an automated luminaire 360. An array of LED light sources 140 directs light into the entrance aperture of light integrator 306. Within light integrator 306 variation in path length and the different numbers of reflections causes homogenization of the light beams. Light exiting the light integrator 306 is further controlled and directed by optical elements 308 and 310 which may form a conventional condensing lens system, to direct light towards the remainder of the optical system. Although two optical elements 308 and 310 are herein illustrated the invention is not so limited and any optical system as known in the art may be utilized to direct the light.

The emergent homogenized light beam may be directed through a series of optical devices as well known within automated lights. Such devices may include but not be restricted to rotating gobos 362, static gobos 364, iris 366, color mixing systems utilizing subtractive color mixing flags, color wheels, framing shutters, frost and diffusion filters and, beam shapers. The final light beam may then pass through a series of objective lenses 368 and 370 which may provide variable beam angle or zoom functionality as well as the ability to focus on various components of the optical system before emerging as the required light beam.

Optical elements such as rotating gobos 362, static gobos 364, color mixing systems, color wheels and iris 366 may be controlled and moved by motors 372. Motors 372 may be stepper motors, servo motors or other motors as known in the art.

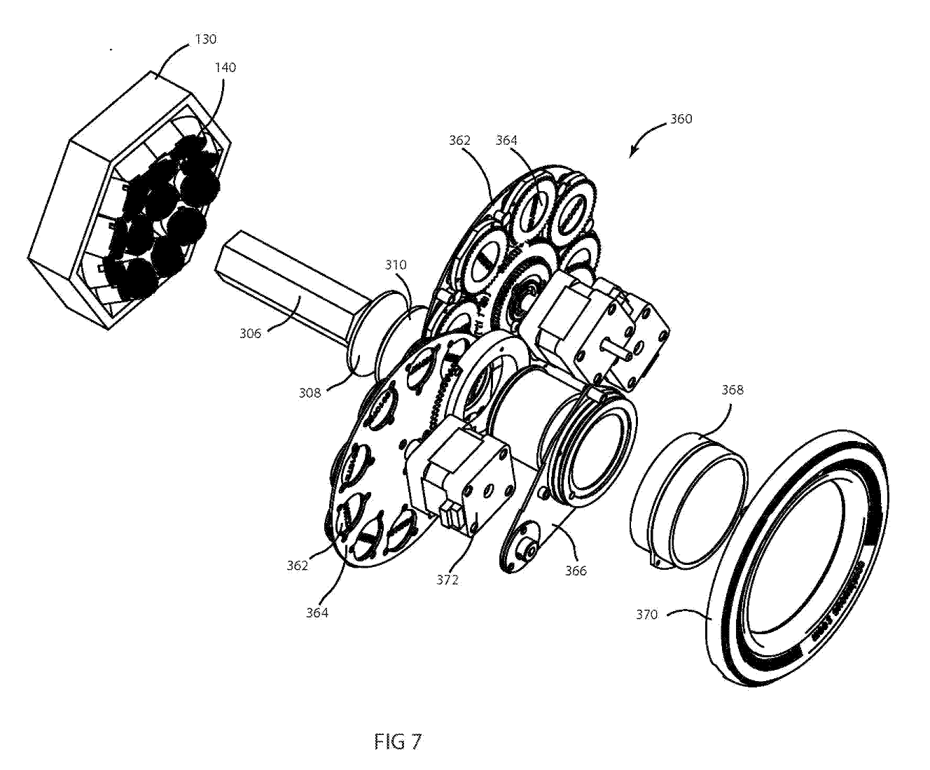

FIG. 7 illustrates a perspective view of an exemplary embodiment 360 of the invention as it may be used in an automated luminaire 360. An array of LED light sources 140 directs light into the entrance aperture of light integrator 306. Within light integrator 306 variation in path length and the different numbers of reflections causes homogenization of the light beams. Light exiting the light integrator 306 is further controlled and directed by optical elements 308 and 310 which may form a conventional condensing lens system, to direct light towards the remainder of the optical system. Although two optical elements 308 and 310 are herein illustrated the invention is not so limited and any optical system as known in the art may be utilized to direct the light.

The emergent homogenized light beam may be directed through a series of optical devices as well known within automated lights. Such devices may include but not be restricted to rotating gobo wheel 362 containing multiple patterns or gobos 624, static gobo wheel 364 containing multiple patterns or gobos 622, iris 366, color mixing systems utilizing subtractive color mixing flags, color wheels, framing shutters, frost and diffusion filters and, beam shapers. The final light beam may then pass through a series of objective lenses 368 and 370 which may provide variable beam angle or zoom functionality as well as the ability to focus on various components of the optical system before emerging as the required light beam.

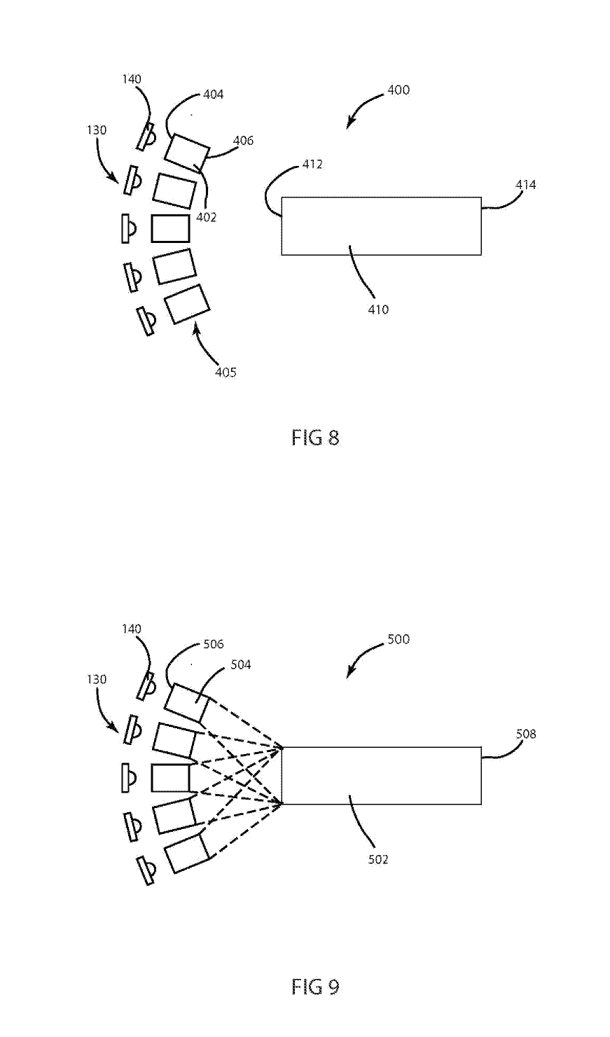

FIG. 8 illustrates a further embodiment 400 of the invention incorporating individual light integrators 402. Each element 140 in an array 130 of LED light sources 140 directs light into the associated entrance aperture 404 of an array of light integrators 405. Within light integrators 402 the light beams may reflect from the walls any number of times from zero to a number defined by the geometry of the tube and the entrance angle and position of the incident light. This variation in path length and the different numbers of reflections causes homogenization of the light beams within light integrators 402. The light integrators 402 further serve to move the effective optical position of the LED light sources 140 closer together and closer to the main integrator 410. The output of the array of light integrators 405 is optionally directed into main light integrator 410 as disclosed in FIG. 4 and FIG. 5. Alternatively the output of light integrators 402 may directly enter the aperture (not shown) and other optical systems (not shown) of the luminaire with no need for further integration of homogenization.

FIG. 9 illustrates a further embodiment 500 of the invention similar to the embodiment 400 illustrated in FIG. 8. The embodiment 500 in FIG. 9 illustrates an integrator that incorporates both the main integrator 410 with the individual LED light integrators 402. The integrator 502 has multiple extensions 504 with entry apertures 506 for receiving light from the LEDs 140 in the array 130.

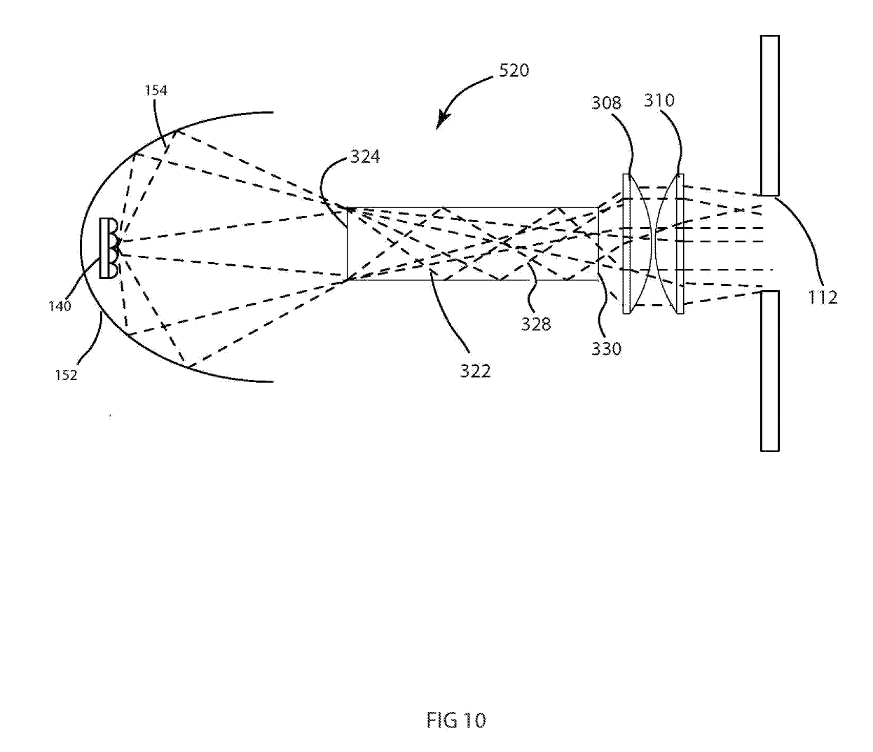

FIG. 10 illustrates a layout diagram of an embodiment of the invention showing the approximate path of light as it passes through the system 520. An LED or an array of LED light sources 140 may be mounted within reflector 152 such that light 154 is directed both directly, and via reflection from reflector 152, into the entrance aperture 324 of light integrator 322. Reflector 152 may be an ellipsoidal reflector, a spherical reflector, a parabolic reflector or other aspheric reflector shapes as well known in the art. Light source 140 may be positioned at or near to a focal point of reflector 152. Within light integrator 322 the light beams 328 may reflect from the walls any number of times from zero to a number defined by the geometry of the tube 322 and the entrance angle and position of the incident light. This variation in path length and the different numbers of reflections causes homogenization of the light beams within light integrator 322. Light exiting the light integrator 322 is optionally further controlled and directed by optical elements 308 and 310 which may form a condensing lens system, to collimate and direct light towards aperture 112. Condensor lens systems tend to collimate the light and produce a more parallel beam. Although two optical elements 308 and 310 are herein illustrated the invention is not so limited and any optical system as known in the art may be utilized to direct the exit beam towards aperture 112.

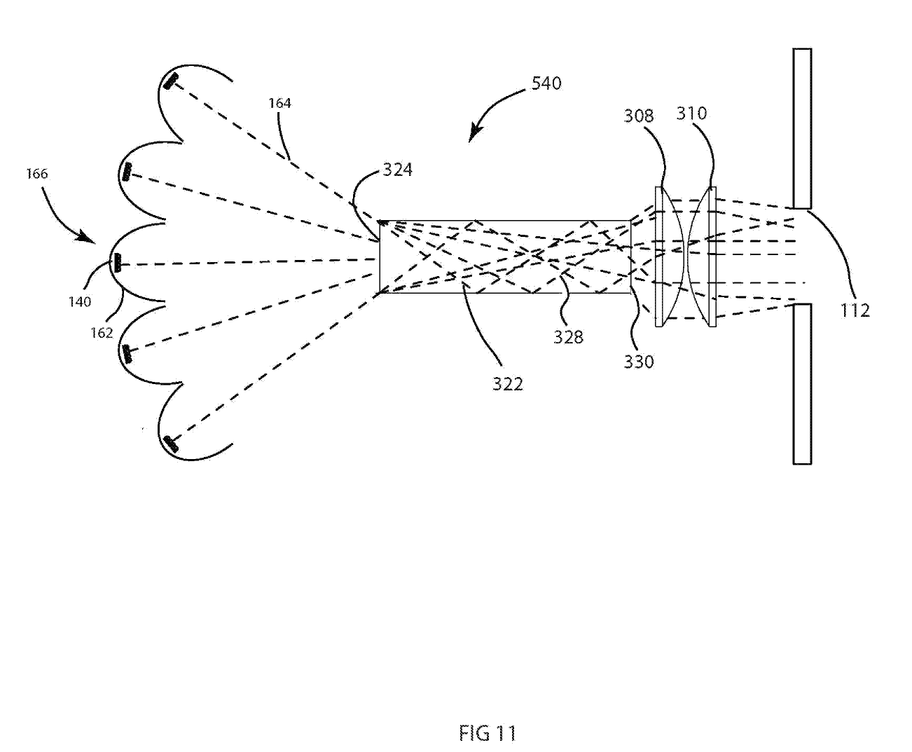

FIG. 11 illustrates a layout diagram of an embodiment of the invention showing the approximate path of light as it passes through the system 540. Multiple LED or arrays of LED light sources 140 may each be mounted within reflectors 162 such that light 164 is directed both directly, and via reflection from reflectors 162, into the entrance aperture 324 of light integrator 322. Reflectors 162 may be ellipsoidal reflectors, spherical reflectors, parabolic reflectors or other aspheric reflector shapes as well known in the art. Light sources 140 may be positioned at or near to focal points of reflectors 162. Within light integrator 322 the light beams 328 may reflect from the walls any number of times from zero to a number defined by the geometry of the tube 322 and the entrance angle and position of the incident light. This variation in path length and the different numbers of reflections causes homogenization of the light beams within light integrator 322. Light exiting the light integrator 322 is optionally further controlled and directed by optical elements 308 and 310 which may form a condensing lens system, to collimate and direct light towards aperture 112. Condensor lens systems tend to collimate the light and produce a more parallel beam. Although two optical elements 308 and 310 are herein illustrated the invention is not so limited and any optical system as known in the art may be utilized to direct the exit beam towards aperture 112.

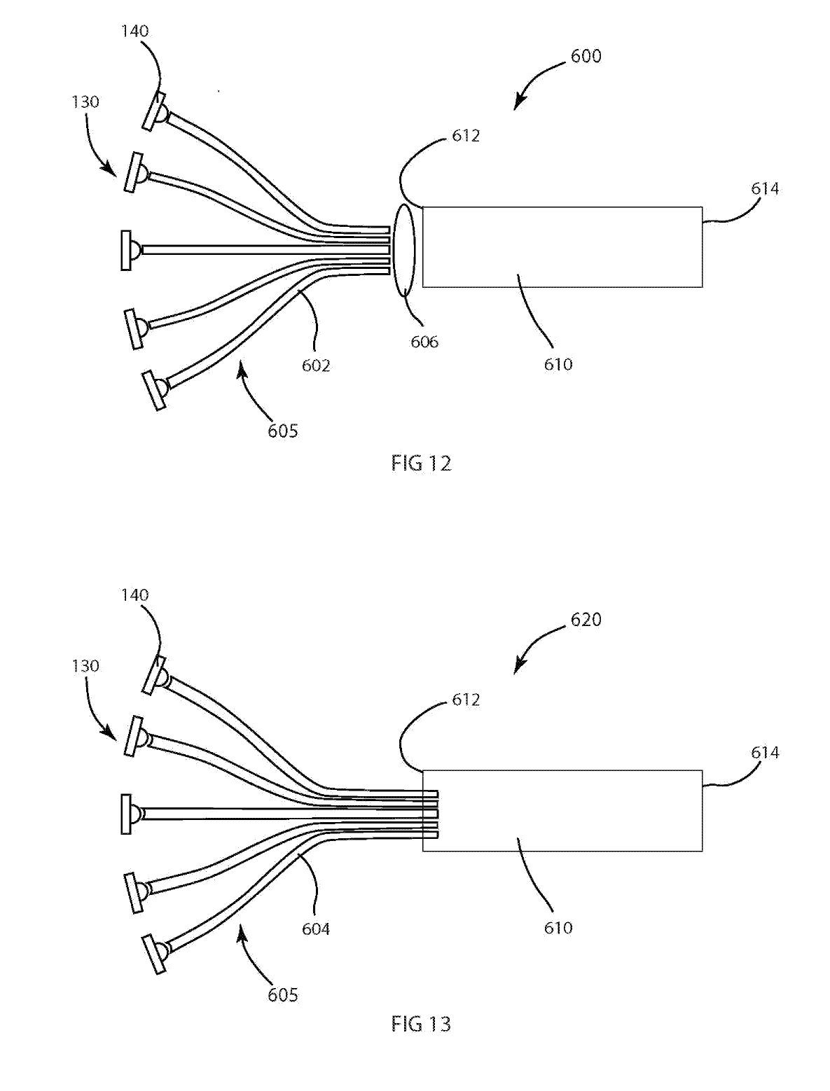

FIG. 12 illustrates a further embodiment 600 of the invention incorporating individual fiber optic integrators 602. Each element 140 in an array 130 of LED light sources 140 directs light into the associated entrance aperture of an array 605 of fiber optic integrators 602. The mechanism of total internal reflection within a solid fiber optic whose refractive index is greater than the surrounding air is well known to those skilled in the art. Within fiber optic integrators 602 the light beams may reflect from the walls any number of times from zero to a number defined by the geometry of the fiber and the entrance angle and position of the incident light. This variation in path length and the different numbers of reflections causes homogenization of the light beams within fiber optic integrators 602. The fiber optic integrators 602 further serve to move the effective optical positions of the LED light sources 140 closer together and closer to the main integrator 610 while separating the LED light sources 140 so as to facilitate their heat management. The output of the array of fiber optic integrators 605 is optionally directed into main light integrator 610 as disclosed in FIG. 4 and FIG. 5. Alternatively the output of light integrators 602 may directly enter the aperture (not shown) and other optical systems (not shown) of the luminaire with no need for further integration or homogenization. Light entering the main light integrator 610 may be further controlled and directed by optical elements 606 which may form an optional condensing lens system, to collimate and direct light towards entrance aperture 612. Condensor lens systems tend to collimate the light and produce a more parallel beam.

Although a single optical element 606 is herein illustrated the invention is not so limited and any optical system as known in the art may be utilized to direct the exit beam towards aperture 612. In alternative embodiments the optical element can be removed and the terminal/output ends of the elongated integrators are shaped to serve the function served by the condensor lens 606.

FIG. 13 illustrates another embodiment 620. In this alternative embodiment, a plurality of the plurality of individual light integrators 604 may abut or enter the aperture 612 of the main light integrator 610. This embodiment differs from the embodiment 600 from FIG. 12 in that there is no optical element 606 between the light integrators and the main light integrator.

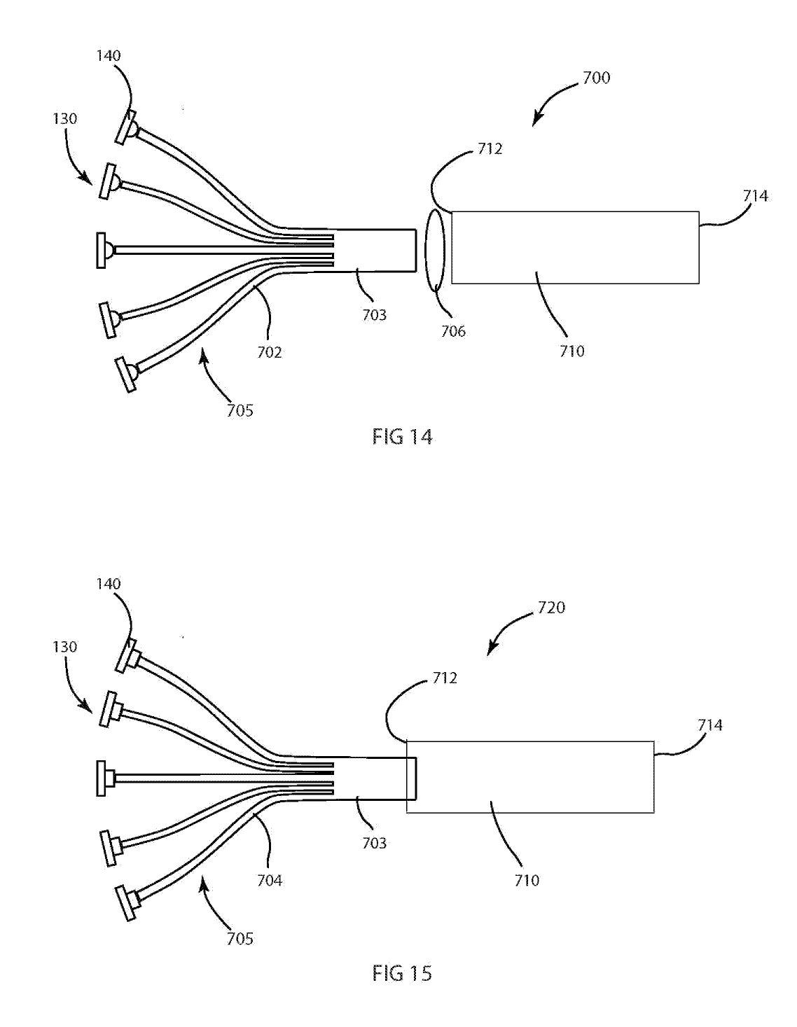

FIG. 14 illustrates a further embodiment 700 of the invention incorporating individual fiber optic integrators 702. Each element 140 in an array 130 of LED light sources 140 directs light into the associated entrance aperture of an array 705 of fiber optic integrators 702. Each element 140 may incorporate an output lens such that light is directed into the entrance apertures of fiber optic integrators 702. The mechanism of total internal reflection within a solid fiber optic whose refractive index is greater than the surrounding air is well known to those skilled in the art. Within fiber optic integrators 702 the light beams may reflect from the walls any number of times from zero to a number defined by the geometry of the fiber and the entrance angle and position of the incident light. This variation in path length and the different numbers of reflections causes homogenization of the light beams within fiber optic integrators 702. Separate fiber optic integrators 702 may be combined into a single larger fiber optic integrator portion 703 such that a single homogenized light beam entrained by total internal reflection is produced as a combination of the output from all light sources 140. The fiber optic integrators 702 and 703 further serve to move the effective optical positions of the LED light sources 140 closer together and closer to the main integrator 710 while separating the LED light sources 140 so as to facilitate their heat management. The output of fiber light integrator 703 is optionally directed into main light integrator 710 as disclosed in FIG. 4 and FIG. 5. Alternatively the output of fiber light integrator 703 may directly enter the aperture (not shown) and other optical systems (not shown) of the luminaire with no need for further integration or homogenization. Light entering the main light integrator 710 may be further controlled and directed by optical elements 706 which may form an optional condensing lens system, to collimate and direct light towards entrance aperture 712. Condensor lens systems tend to collimate the light and produce a more parallel beam. Although a single optical element 706 is herein illustrated the invention is not so limited and any optical system as known in the art may be utilized to direct the exit beam towards aperture 712.

FIG. 15 illustrates a further embodiment 720 of the invention illustrated in FIG. 14 incorporating individual fiber optic integrators 704. Each element 140 in an array 130 of LED light sources 140 directs light into the associated entrance aperture of an array 705 of fiber optic integrators 704. Each element 140 may utilize LEDs manufactured with a photonic lattice output such that light is directed into the entrance apertures of fiber optic integrators 704. The embodiment 720 illustrated in FIG. 15 also differs from the embodiment 700 illustrated in FIG. 14 in the absence of optical element 706 and abutting or inserting the light integrator portion 703 against/into the aperture 712 of main integrator 710.

In alternative embodiments of the embodiments illustrated in FIG. 14 and FIG. 15, if the larger integrator portion 703 is sufficiently long, there may be no need for the main integrator 710.

In each of the embodiments described and in further embodiments, the LED light sources 140 may be a single LED or a sub-array of LEDs and may be of a single color and type or may be of multiple colors such as a mix of Red, Green and Blue LEDs. Any number and mix of colors of LEDs may be used within each LED light source 140 without departing from the spirit of the invention.

While the invention has been described with respect to a limited number of embodiments, those skilled in the art, having benefit of this disclosure, will appreciate that other embodiments may be devised which do not depart from the scope of the disclosure as disclosed herein. The invention has been described in detail, it should be understood that various changes, substitutions and alterations can be made hereto without departing from the spirit and scope of the disclosure.

What is claimed is:

1. A multi-parameter luminaire comprising:
a plurality of reflector mounted light sources emitting light directed toward an inlet aperture of
an elongated light beam integrator which receives the light from the plurality of light sources and homogenizes the light via internal reflection toward an outlet aperture.

2. The multi-parameter luminaire of claim 1 wherein:
A plurality of the light sources are an array of LEDs mounted in a reflector.

3. The multi-parameter luminaire of claim 1 wherein:
A plurality of the light sources are individual LEDs and/or arrays of LEDs mounted in a plurality of reflectors.

4. The multi-parameter luminaire of claim 1 wherein the plurality of light sources generate light in a plurality of individual colors.

5. The multi-parameter luminaire of claim 1 wherein:
the light beam integrator is hollow with a reflective internal surface.

6. The multi-parameter luminaire of claim 1 wherein:
the light beam integrator is solid and constructed of material(s) that results in internal reflectance for the angle of incidence of the light entering the inlet aperture of the light beam integrator.

7. The multi-parameter luminaire of claim 5 wherein
the elongated light beam integrator has a smooth sided cross-section.

8. The multi-parameter luminaire of claim 7 wherein
the smooth sided cross-section is circular.

9. The multi-parameter luminaire of claim 5 wherein:
the elongated light beam integrator has a polygonal cross-section.

10. The multi-parameter luminaire of claims 9 wherein:
the polygonal cross section of the light beam integrator matches the shape of the array of the plurality of cross-sections.

11. The multi-parameter luminaire of claim 1 wherein:
the light sources are configured in a two dimensional array.

12. The multi-parameter luminaire of claim 1 wherein:
the light sources are configured in the two dimensional array is configured in a three-dimensional space.
. The multi-parameter luminaire of claim 12 wherein:
the light sources are generally configured in ellipsoidal fashion with the first focus near the center of the inlet aperture of the beam integrator.

14. The light multi-parameter luminaire of claim 1 wherein:
the cross-sectional area of the inlet aperture of the light beam integrator is smaller than the cross-sectional area of the outlet aperture of the light beam integrator.

15. A light-beam engine comprising:
a plurality of light sources emitting light directed toward inlet apertures of
a plurality of elongated light beam integrators which receive the light from the plurality of light sources and homogenizes the light via internal reflection; and
the homogenized light from the plurality of elongated light beam integrators is input into a light beam integrator which integrates the light from the plurality of elongated light beam integrators toward an outlet aperture.

16. The light-beam engine of claim 15 wherein:
A plurality of the light sources are individual LEDs and/or arrays of LEDs.

17. The light-beam engine of claim 15 wherein the plurality of light sources generate light in a plurality of individual colors.

18. The light-beam engine of claim 15 wherein:
the light beam integrator is hollow with a reflective internal surface.

19. The light-beam engine of claim 15 wherein:
the light beam integrator is solid and constructed of material(s) that results in internal reflectance for the angle of incidence of the light entering the inlet aperture of the light beam integrator.

20. The light-beam engine of claim 18 wherein
the elongated light beam integrator has a smooth sided cross-section.

21. The light-beam engine of claim 20 wherein
the smooth sided cross-section is circular.

22. The light-beam engine of claim 18 wherein:
the elongated light beam integrator has a polygonal cross-section.

23. The light-beam engine of claims 22 wherein:
the polygonal cross section of the light beam integrator matches the shape of the array of the plurality of cross-sections.

24. The light-beam engine of claim 15 wherein:
the light sources are configured in an two dimensional array.

25. The light-beam engine of claim 15 wherein:
the light sources are configured in the two dimensional array is configured in a three-dimensional space.

26. The light-beam engine of claim 16 wherein:
the LED sources are covered by lenses which serve to focus/direct the light toward an elongated light-beam integrator.

27. The light-beam engine of claim 16 which further comprises a:
a condensor lens between the elongated light beam integrators and the light beam integrator.

28. The light-beam engine of claim 16 which further comprises a condensor lens which receives the light output of the light beam integrator.
